(19) United States
(12) Patent Application Publication
(10) Pub. No.: US 2024/0186265 A1
(43) Pub. Date: Jun. 6, 2024

(54) SHIELDED GATE TRENCH MOSFETS WITH HEXAGONAL DEEP TRENCH LAYOUTS AND MULTIPLE EPITAXIAL LAYERS

(71) Applicant: Nami MOS CO., LTD., New Taipei City (TW)

(72) Inventor: FU-YUAN HSIEH, New Taipei City (TW)

(73) Assignee: Nami MOS CO., LTD., New Taipei City (TW)

(21) Appl. No.: 18/073,964

(22) Filed: Dec. 2, 2022

(51) Int. Cl. H01L 23/00; H01L 29/10; H01L 29/40; H01L 29/423; H01L 29/739; H01L 29/78

(52) U.S. Cl. CPC H01L 23/562; H01L 29/1095; H01L 29/404; H01L 29/407; H01L 29/4238; H01L 29/7395; H01L 29/7397; H01L 29/7802; H01L 29/7813

(57) ABSTRACT

A shielded gate trench (SGT) MOSFET structure with a hexagonal deep trench layout and multiple epitaxial layers for wafer warpage and on-resistance reductions is disclosed, wherein a gate electrode surrounds the deep trench in each unit cell as a closed cell. A source-body contact is disposed between the gate electrode and the deep trench. Moreover, the gate electrode is planar, or vertically formed in an upper portion of a gate trench in each unit cell.

### FIELD OF THE INVENTION

This invention relates to a novel and improved cell layout and device configuration of a shielded gate trench (SGT) metal oxide semiconductor field effect transistor (MOSFET) with multiple epitaxial layers to solve wafer warpage issue and reduce specific on-resistance of the device in medium and high voltage ranges.

### BACKGROUND OF THE INVENTION

Compared with the conventional trench MOSFETs, SGT MOSFETs are more attractive due to lower specific drain-source resistance (Rds) and improved overall efficiency in most applications without compromising ruggedness of the device. However, a number of problems related to manufacturability and device characteristics impose a number of challenges. The wafer warpage becomes a serious issue when wafer diameter and die size increases or breakdown voltage increases. Main reasons for the rise of the wafer warpage are given by increasing trench depth and increasing field oxide thickness as breakdown voltage increases. When the wafer warpage exceeds a critical value, an error in vacuum absorption or wafer transportation occurs in some equipment. The wafers cannot be processed any more.

A conventional SGT MOSFET disclosed in U.S. Pat. No. 9,882,043 having a gate pad 10 and multiple gate trenches 21 and 22 with stripe shape in an active area 20 is shown in FIG. 1, wherein a single trench termination 40 in a termination area 30 surrounds the multiple gate trenches 21 and 22. The wafer warpage is not only related to the field oxide thickness and the trench depth increasement, but also relates to length of the gate trenches. The longer the length of the gate trench, the more the wafer warpage.

Therefore, there is still a need in the art of the semiconductor power device, particularly for the SGT MOSFET design and fabrication, to provide a novel cell structure, device configuration and fabrication process that would resolve these difficulties and design limitations.

### SUMMARY OF THE INVENTION

An object of the present disclosure is to provide a SGT device having a plurality of deep trenches, wherein each of the deep trenches has a hexagonal shape for the wafer warpage reduction. Since breakdown voltage of the shielded gate is very sensitive to a mesa width between the adjacent deep trenches, the hexagonal shape layout is chosen to ensure that all the mesa widths in different directions are the same. Moreover, the hexagonal deep trench has much less stress than the stripe deep trench.

Another object of the present disclosure is to provide a SGT device having different gate electrode structures and multiple stepped epitaxial (MSE) layers for further improving DC and AC performance.

The present invention features a SGT MOSFET comprising a plurality of unit cells with each unit cell in an active area having an oxide charge balance (OCB) region formed in a mesa area between the adjacent deep trenches, comprising: a substrate of a first conductivity type; an epitaxial layer of the first conductivity type grown on the substrate; each of the unit cells has a deep trench with a hexagonal shape filled with a shielded gate electrode surrounded by a first insulating film as a field plate oxide, starting from a top surface of the epitaxial layer toward the substrate; a planar gate electrode in each of the unit cell padded by a gate oxide surrounding the deep trench with a hexagonal shape; a source region of the first conductivity type surrounding an upper portion of a trenched source-body contact with a hexagonal shape, extending between the planar gate electrode and the adjacent deep trench, a body region of the second conductivity type underneath the source region; the trenched source-body contact filled with a contact metal plug extending into the body region in the mesa area.

According to another aspect of the present invention, a SGT MOSFET comprising a plurality of unit cells with each unit cell in an active area having an oxide charge balance (OCB) region formed in a mesa area between the adjacent deep trenches, comprising: a substrate of a first conductivity type; an epitaxial layer of the first conductivity type grown on the substrate; each of the unit cells has a deep trench with a hexagonal shape filled with a first type shielded gate electrode surrounded by a first insulating film as a field plate oxide, starting from a top surface of the epitaxial layer toward the substrate; a gate trench having a hexagonal shape surrounded by a source region of the first conductivity type are encompassed in a body region of a second conductivity type near a top surface of the epitaxial layer, the gate trench is filled with a gate electrode and a second type shielded gate electrode; the second type shielded gate electrode is insulated from the epitaxial layer by a second insulating insulating film, the gate electrode is insulated from the epitaxial layer by a gate oxide, the second type shielded gate electrode and the gate electrode are insulated from each other by an (Inter-Poly Oxide) IPO film, the gate oxide surrounds the gate electrode and has less thickness than the second insulating film; the body region, the first type and second type shielded gate electrodes, and the source region are shorted together to a source metal through a trench source-body contact having a hexagonal shape.

According to another aspect of the present invention, in some preferred embodiments, the epitaxial layer is a single epitaxial layer with a uniform doping concentration. In some other preferred embodiments, the epitaxial layer has multiple stepped epitaxial (MSE) layers with different doping concentrations decreasing stepwise in a direction from substrate to the body regions, wherein each of the MSE layers has a uniform doping concentration as grown.

According to another aspect of the present invention, the epitaxial layer has multiple stepped epitaxial (MSE) layers between the body region and a bottom of the shielded gate electrode in the deep trench with different doping concentrations decreasing stepwise in a direction from bottoms of the plurality of shielded gate electrodes in the deep trenches toward the body regions along sidewalls of the plurality of deep trenches, and a buffer epitaxial layer between a bottom of the shielded gate electrode in the deep trench and the substrate, the epitaxial layer in the buffer region has a doping concentration lower than each of the MSE layers.

According to another aspect of the present invention, the epitaxial layer has multiple stepped epitaxial (MSE) layers between the body region and a bottom of the shielded gate electrode in the deep trench with different doping concentrations decreasing stepwise in a direction from bottoms of the plurality of shielded gate electrodes in the deep trenches toward the body regions along sidewalls of the plurality of deep trenches, and a buffer epitaxial layer between a bottom of the shielded gate electrode in the deep trench and the substrate, the epitaxial layer in the buffer region has a doping concentration higher than a top layer of the MSE layers but lower than other layers of the MSE layers.

According to another aspect, the present invention also features a SGT insulted gate bipolar transistor (IGBT) which is formed in an epitaxial layer of a first conductivity type onto a substrate of the second conductivity type.

According to another aspect, in some preferred embodiments, the SGT IGBT further comprising a plurality of heavily doped regions of the first conductivity type in a substrate of the second conductivity type to form a plurality of alternating P+ and N+ regions in the substrate.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a top view of a conventional SGT MOSFET.

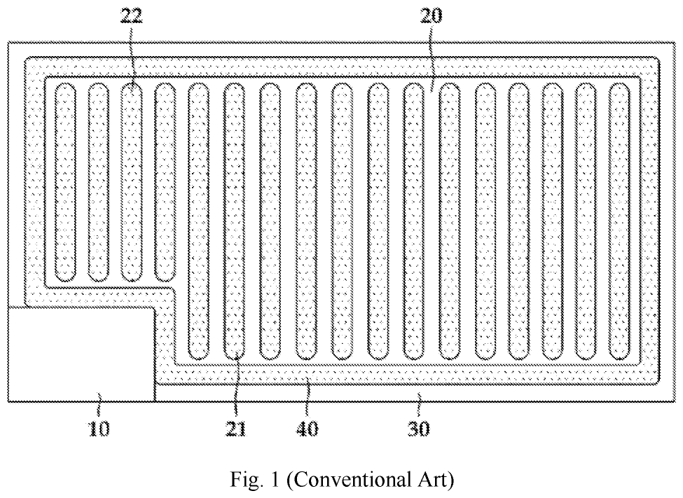

FIG. 2A is a top view of a preferred embodiment with a planar gate electrode according to the present invention.

FIG. 2B is a cross-sectional view of a SGT MOSFET showing a preferred embodiment along A1-A1′ line of FIG. 2A according to the present invention.

FIG. 3A is a top view of another preferred embodiment with gate trenches according to the present invention.

FIG. 3B is a cross-sectional view of a SGT MOSFET showing a preferred embodiment along A2-A2′ line of FIG. 3A according to the present invention.

FIG. 4A is a cross-sectional view of a SGT MOSFET showing another preferred embodiment along A1-A1′ line of FIG. 2A wherein the doping concentration variations are depicted along the vertical direction according to the present invention.

FIG. 4B is a cross-sectional view of a SGT MOSFET showing another preferred embodiment along A1-A1′ line of FIG. 2A wherein the doping concentration variations are depicted along the vertical direction according to the present invention.

FIG. 4C is a cross-sectional view of a SGT MOSFET showing another preferred embodiment along A1-A1′ line of FIG. 2A wherein the doping concentration variations are depicted along the vertical direction according to the present invention.

FIG. 4D is a cross-sectional view of a SGT MOSFET showing another preferred embodiment along A1-A1′ line of FIG. 2A wherein the doping concentration variations are depicted along the vertical direction according to the present invention.

FIG. 5A is a cross-sectional view of a SGT MOSFET showing another preferred embodiment along A2-A2′ line of FIG. 3A wherein the doping concentration variations are depicted along the vertical direction according to the present invention.

FIG. 5B is a cross-sectional view of a SGT MOSFET showing another preferred embodiment along A2-A2′ line of FIG. 3A wherein the doping concentration variations are depicted along the vertical direction according to the present invention.

FIG. 5C is a cross-sectional view of a SGT MOSFET showing another preferred embodiment along A2-A2′ line of FIG. 3A wherein the doping concentration variations are depicted along the vertical direction according to the present invention.

FIG. 5D is a cross-sectional view of a SGT MOSFET showing another preferred embodiment along A2-A2′ line of FIG. 3A wherein the doping concentration variations are depicted along the vertical direction according to the present invention.

FIG. 6A is a cross-sectional view of a SGT IGBT showing another preferred embodiment along A1-A1′ line of FIG. 2A wherein the doping concentration variations are depicted along the vertical direction according to the present invention.

FIG. 6B is a cross-sectional view of a SGT IGBT showing another preferred embodiment along A1-A1′ line of FIG. 2A wherein the doping concentration variations are depicted along the vertical direction according to the present invention.

FIG. 6C is a cross-sectional view of a SGT IGBT showing another preferred embodiment along A1-A1′ line of FIG. 2A wherein the doping concentration variations are depicted along the vertical direction according to the present invention.

FIG. 7A is a cross-sectional view of a SGT IGBT showing another preferred embodiment along A1-A1′ line of FIG. 2A wherein the doping concentration variations are depicted along the vertical direction according to the present invention.

FIG. 7B is a cross-sectional view of a SGT IGBT showing another preferred embodiment along A1-A1′ line of FIG. 2A wherein the doping concentration variations are depicted along the vertical direction according to the present invention.

FIG. 7C is a cross-sectional view of a SGT IGBT showing another preferred embodiment along A1-A1′ line of FIG. 2A wherein the doping concentration variations are depicted along the vertical direction according to the present invention.

FIG. 8A is a cross-sectional view of a SGT IGBT showing another preferred embodiment along A2-A2′ line of FIG. 3A wherein the doping concentration variations are depicted along the vertical direction according to the present invention.

FIG. 8B is a cross-sectional view of a SGT IGBT showing another preferred embodiment along A2-A2′ line of FIG. 3A wherein the doping concentration variations are depicted along the vertical direction according to the present invention.

FIG. 8C is a cross-sectional view of a SGT IGBT showing another preferred embodiment along A2-A2′ line of FIG. 3A wherein the doping concentration variations are depicted along the vertical direction according to the present invention.

FIG. 9A is a cross-sectional view of a SGT IGBT showing another preferred embodiment along A2-A2′ line of FIG. 3A wherein the doping concentration variations are depicted along the vertical direction according to the present invention.

FIG. 9B is a cross-sectional view of a SGT IGBT showing another preferred embodiment along A2-A2′ line of FIG. 3A wherein the doping concentration variations are depicted along the vertical direction according to the present invention.

FIG. 9C is a cross-sectional view of a SGT IGBT showing another preferred embodiment along A2-A2′ line of FIG. 3A wherein the doping concentration variations are depicted along the vertical direction according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

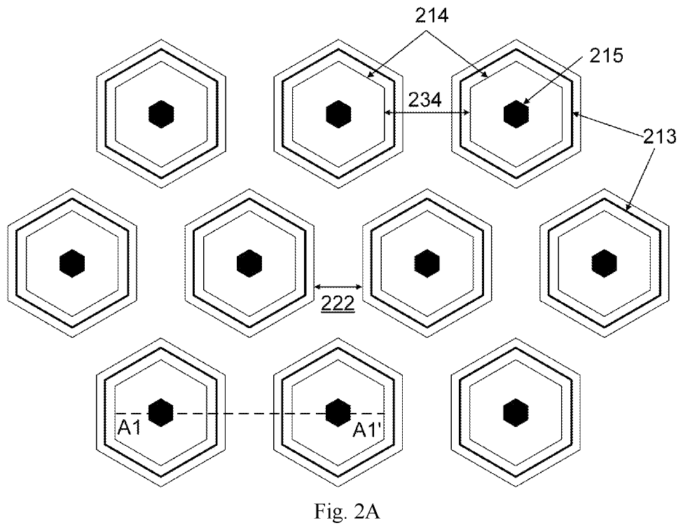

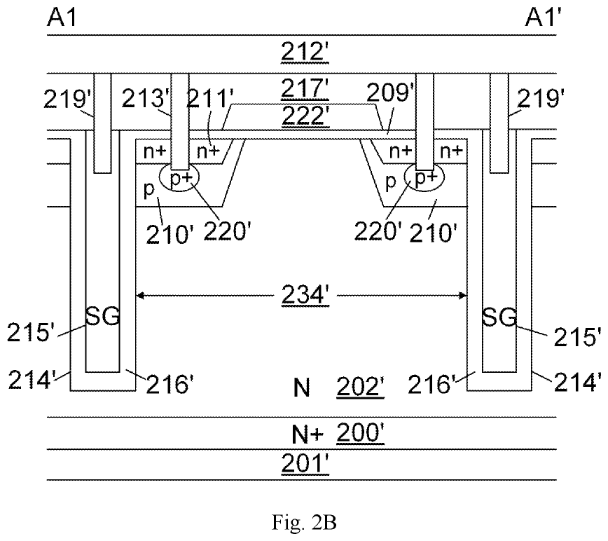

Please refer to FIG. 2A for a top view of a preferred embodiment for an SGT semiconductor power device comprising a plurality of unit cells with each unit cell in an active area having an OCB region formed in a mesa area 234 between the adjacent deep trenches 214. Each of the unit cells has a deep trench 214 with a hexagonal shape filled with a shielded gate contact 215 and surrounded by a gate poly silicon layer 222 as a gate electrode. Moreover, a source-body contact 213 with a hexagonal shape is formed between the gate poly silicon layer 222 and the deep trench 214.

Please refer to FIG. 2B for a cross-sectional view showing a preferred A1-A1′ cross section of FIG. 2A with a single epitaxial layer according to the present invention. The preferred embodiment comprises an N-channel SGT MOSFET formed in an N type epitaxial layer 202′ onto an N+ substrate 200′ coated with a back metal 201′ of Ti/Ni/Ag on rear side as a drain metal. Inside the N type epitaxial layer 202′, a plurality of deep trenches 214′ are formed vertically downward from a top surface of the N type epitaxial layer 202′ and not reaching the common interface between the N type epitaxial layer 202′ and the N+ substrate 200′. Each deep trench 214′ is filled with a shielded gate electrode 215′ (SG, as illustrated) surrounded by a first insulating film 216′ as a field plate oxide. A planar gate poly silicon layer as a gate electrode 222′ padded by a gate oxide 209′ is formed, wherein the gate oxide 209′ has a thinner thickness than the first insulating film 216′. Between the planar gate electrode 222′ and the adjacent deep trench 214′, the P body regions 210′ with n+ source regions 211′ thereon are extending near top surface of the N type epitaxial layer 202′. The P body regions 210′, the n+ source regions 211′, and the shielded gate electrode 215′ are further shorted together to a source metal 212′ through a plurality of trenched contacts 213′ or 219′ filled with contact plugs and barriers implemented by penetrating through a contact insulating layer 217′ and into p+ heavily doped regions 220′ around bottoms underneath the n+ source regions 211′ or the shielded gate electrode 215′. According to the invention, an OCB region is therefore formed in a mesa area 234′ between the adjacent of the deep trenches 214′.

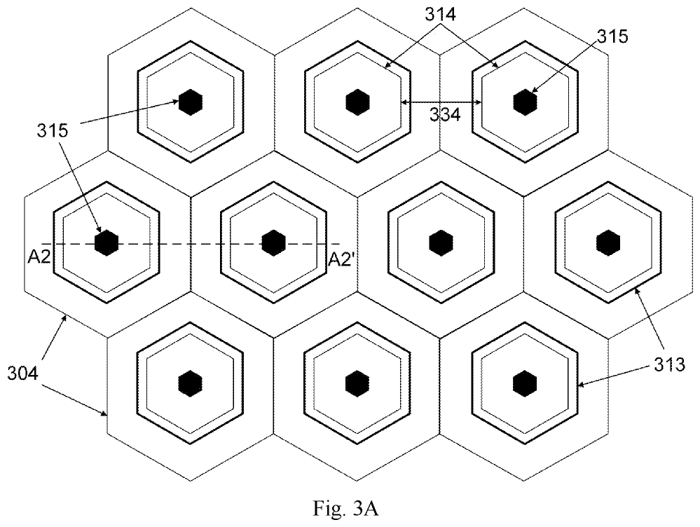

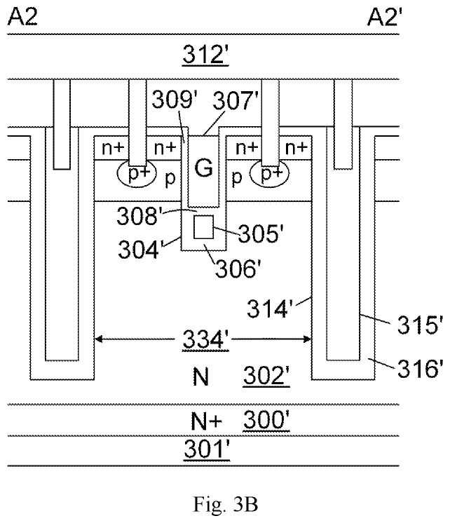

Please refer to FIG. 3A for a top view of another preferred embodiment for an SGT semiconductor power device comprising a plurality of unit cells with each unit cell in an active area having an oxide charge balance (OCB) region formed in a mesa area 334 between the adjacent deep trenches 314. Each of the unit cells has a deep trench 314 with a hexagonal shape filled with a shielded gate contact 315, wherein a gate trench 304 having a hexagonal shape surrounds the deep trench 314 with a hexagonal shape in each unit cell as a closed shape in an active area. Moreover, a source-body contact 313 with a hexagonal shape is formed between the gate trench 304 and the deep trench 314.

Please refer to FIG. 3B for a cross-sectional view showing a preferred A2-A2′ cross section of FIG. 3A with new and improved device structure with a single epitaxial layer according to the present invention. The N-channel trenched semiconductor power device has a similar structure to FIG. 2B, except for the gate trench structure 304′ in the mesa area 334′. In FIG. 3B, at least one gate trench 304′ is formed surrounding a deep trench 314′ as a closed shape in an active area, wherein there are multiple closed shape cells in the active area. Each deep trench 314′ is filled with a first type shielded gate electrode 315′ surrounded by a first insulating film 316′ as a field plate oxide. In a mesa area between the adjacent deep trenches 314′, said at least one gate trench 304′ is formed extending from a top surface of the N type epitaxial layer 302′ and vertically downward into the N type epitaxial layer 302′, wherein the gate trench 304′ has a shallower trench depth than the deep trench 314′. Inside each of the gate trenches 304′, a second type shielded gate electrode 305′ is disposed in the lower portion and a single gate electrode (G, as illustrated) 307′ is disposed in the upper portion above the shielded gate electrode 305′. The second type shielded gate electrode 305′ is insulated from the adjacent epitaxial layer by a second insulating film 306′, and the gate electrodes 307′ is insulated from the adjacent epitaxial layer by a gale oxide 309′, wherein the gate oxide 309′ has a thinner thickness than the second insulating film 306′ which has a uniform thickness along trench sidewalls, meanwhile, the second type shielded gate electrode 305′ and the gate electrode 307′ are insulated from each other by an IPO film 308′.

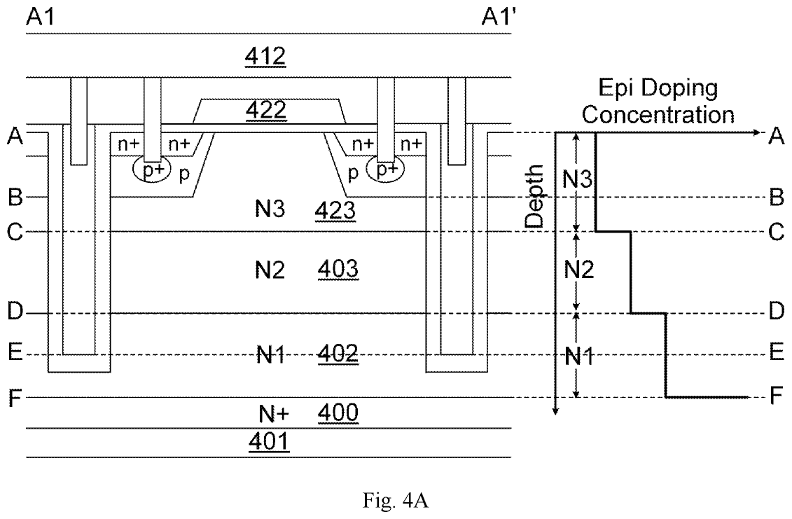

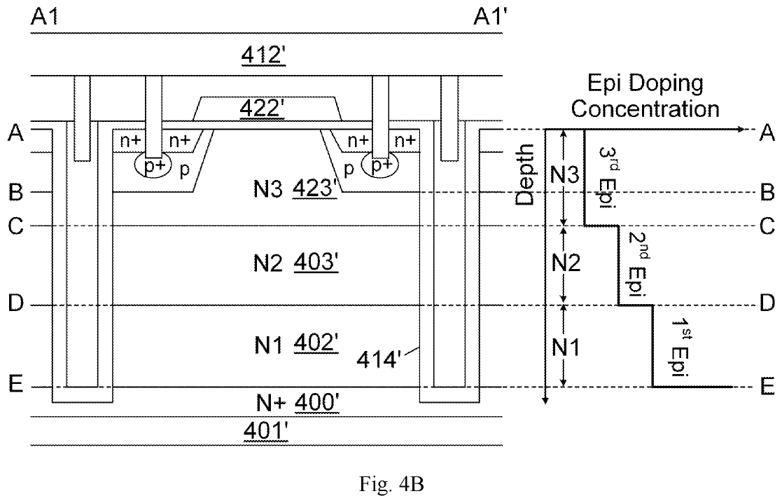

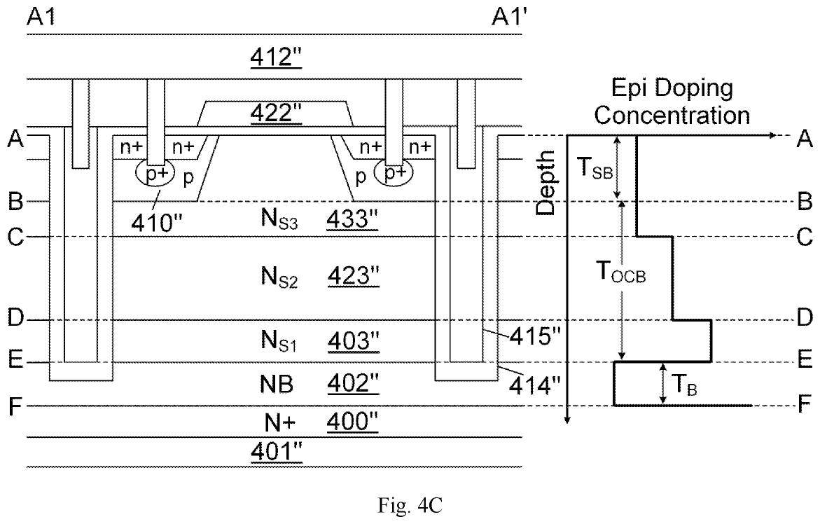

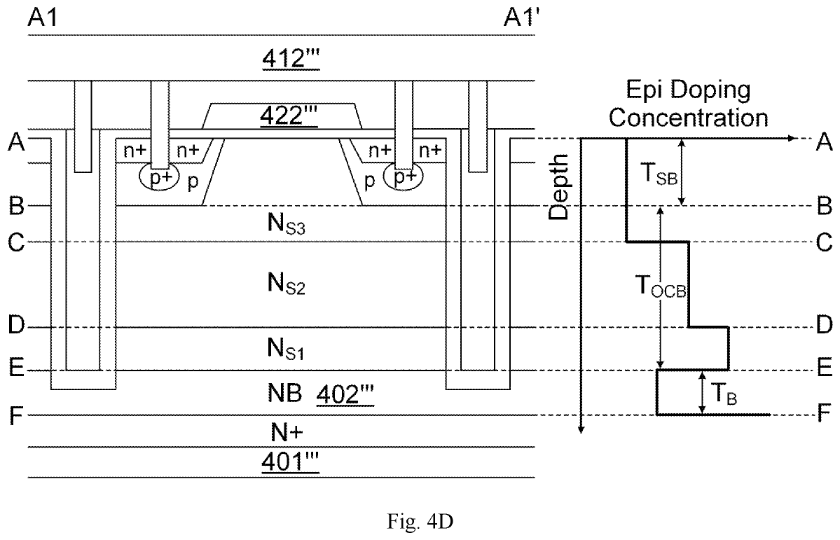

Please refer to FIG. 4A for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device has a similar structure to FIG. 2B, except that, in FIG. 4A, the N type epitaxial layer comprises three stepped epitaxial layers of different doping concentration including a bottom 1^{st} epitaxial layer (N1, as illustrated between D-D and F-F lines) 402 a with doping concentration D1, a middle 2^{nd} epitaxial layer (N2, as illustrated between C-C and D-D lines) 403 with a doping concentration D2 and a top 3^{rd} epitaxial layer (N3, as illustrated between A-A and C-C lines) 423 with a doping concentration D3, wherein D3<D2<D1, to further reduce the specific on-resistance. The D2 can be an average of D1 and D3.

Please refer to FIG. 4B for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device has a similar structure to FIG. 4A, except that, a bottom of the deep trench 414′ in this invention is located below a top surface of the N+ substrate 400′ and above a top surface of the back metal 401′.

Please refer to FIG. 4C for a cross-sectional view showing another preferred embodiment along A1-A1′ line of FIG. 2A with new and improved device structure having multiple stepped epitaxial layers wherein the doping concentration variations as grown are depicted along the vertical direction. The N-channel trenched semiconductor power device has a similar structure to FIG. 4A, except for the different epitaxial layer structure. In FIG. 4C, an OCB region T_{OCB} is formed in a mesa area between two adjacent of the deep trenches 414″ below the body regions 410″ and above a bottom of the shielded gate electrode 415″ in the deep trench 414″ (between B-B and E-E lines), a buffer region T_{B} is formed between the N+ substrate 400″ and a bottom of the shielded gate electrode 415″ (between E-E and F-F lines), the epitaxial layer in the OCB region has at least three stepped epitaxial layers with different doping concentrations including a bottom 1^{st} epitaxial layer (N_{S1}, as illustrated between D-D and E-E lines) 403″ above the buffer epitaxial layer (N_{B}, as illustrated between E-E and F-F lines) 402″ with a doping concentration D1, a middle 2^{nd} epitaxial layer (N_{S2}, as illustrated between C-C and D-D lines) 423″ above the 1^{st} epitaxial layer 403″ with a doping concentration D2 and a top 3^{rd} epitaxial layer (N_{S3}, as illustrated between B-B and C-C lines) 433″ above the 2^{nd} epitaxial layer 423″ with a doping concentration D3, wherein D3<D2<D1. The D2 can be an average of D1 and D3. Moreover, the epitaxial layer in the source regions and body regions T_{SB} has a doping concentration same as the top 3^{rd} epitaxial layer 433″ of the MSE layers in the OCB region T_{OCB}, and the buffer epitaxial layer 402″ has a doping concentration D_{B} lower than each of the MSE layers in the OCB region T_{OCB}.

Please refer to FIG. 4D for a cross-sectional view showing another preferred embodiment along A1-A1′ line of FIG. 2A with new and improved device structure having multiple stepped epitaxial layers wherein the doping concentration variations as grown are depicted along the vertical direction. The N-channel trenched semiconductor power device has a similar structure to FIG. 4C, except that in FIG. 4D, the buffer epitaxial layer (N_{B}, as illustrated between E-E and F-F lines) 402′″ has a doping concentration D_{B} higher than a top layer of the MSE layers in the OCB region T_{OCB} but lower than other layers of the MSE layers in the OCB region T_{OCB}.

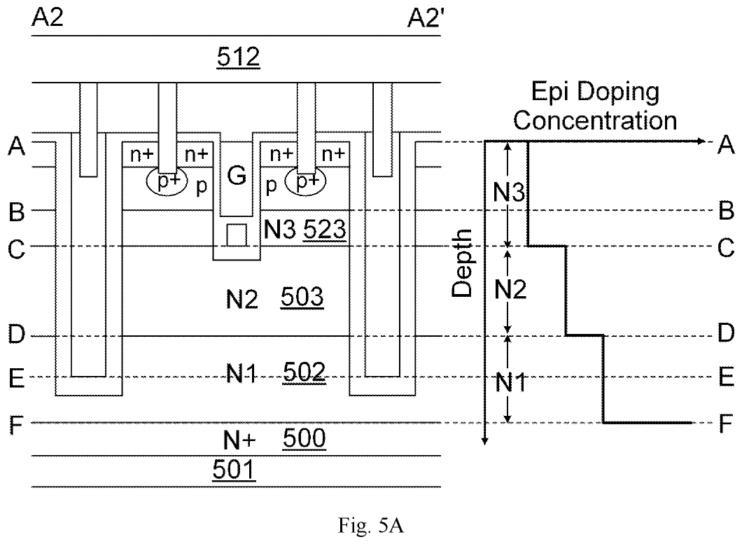

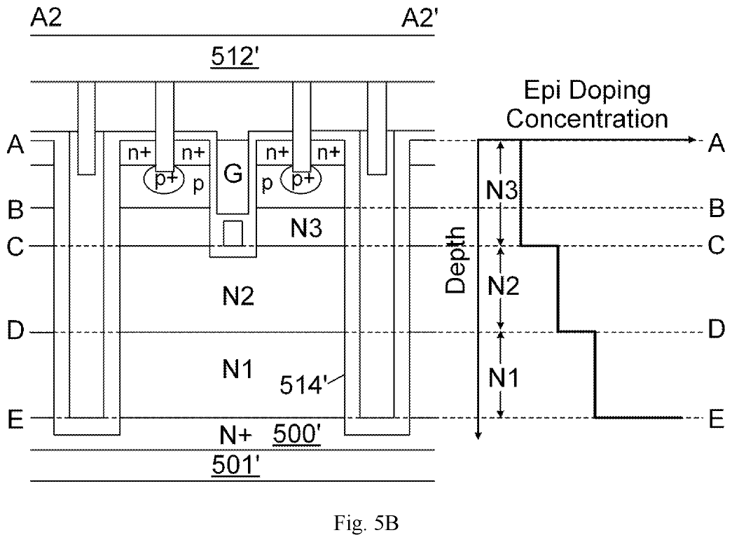

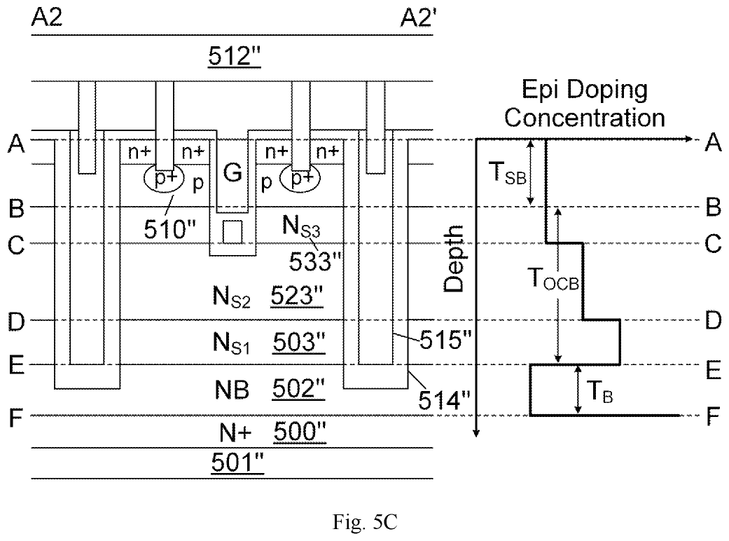

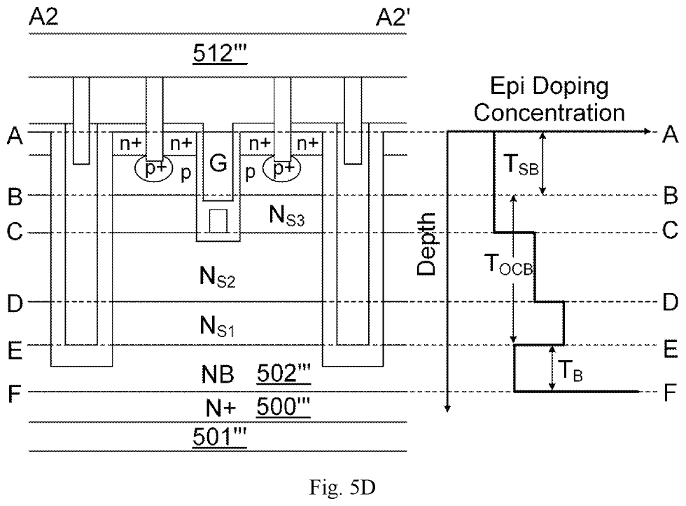

Please refer to FIG. 5A for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device has a similar structure to FIG. 3B, except that, in FIG. 5A, the N type epitaxial layer comprises three stepped epitaxial layers of different doping concentration including a bottom 1^{st} epitaxial layer (N1, as illustrated between D-D and F-F lines) 502 a with doping concentration D1, a middle 2^{nd} epitaxial layer (N2, as illustrated between C-C and D-D lines) 503 with a doping concentration D2 and a top 3^{rd} epitaxial layer (N3, as illustrated between A-A and C-C lines) 523 with a doping concentration D3, wherein D3<D2<D1, to further reduce the specific on-resistance. The D2 can be an average of D1 and D3.

Please refer to FIG. 5B for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device has a similar structure to FIG. 5A, except that, a bottom of the deep trench 514′ in this invention is located below a top surface of the N+ substrate 500′ and above a top surface of the back metal 501′.

Please refer to FIG. 5C for a cross-sectional view showing another preferred embodiment along A2-A2′ line of FIG. 3A with new and improved device structure having multiple stepped epitaxial layers wherein the doping concentration variations as grown are depicted along the vertical direction. The N-channel trenched semiconductor power device has a similar structure to FIG. 5A, except for the different epitaxial layer structure. In FIG. 5C, an OCB region T_{OCB} is formed in a mesa area between two adjacent of the deep trenches 514″ below the body regions 510″ and above a bottom of the first type shielded gate electrode 515″ (between B-B and E-E lines), a buffer region T_{B} is formed between the N+ substrate 500″ and a bottom of the first type shielded gate electrode 515″ (between E-E and F-F lines), the epitaxial layer in the OCB region has three stepped epitaxial layers with different doping concentrations including a bottom 1^{st} epitaxial layer (N_{S1}, as illustrated between D-D and E-E lines) 503″ above the buffer epitaxial layer (N_{B}, as illustrated between E-E and F-F lines) 502″ with a doping concentration D1, a middle 2^{nd} epitaxial layer (N_{S2}, as illustrated between C-C and D-D lines) 523″ above the 1^{st} epitaxial layer 503″ with a doping concentration D2 and a top 3^{rd} epitaxial layer (N_{S3}, as illustrated between B-B and C-C lines) 533″ above the 2^{nd} epitaxial layer 523″ with a doping concentration D3, wherein D3<D2<D1. The D2 can be an average of D1 and D3. Moreover, the epitaxial layer in the source regions and body regions T_{SB} has a doping concentration same as the top 3^{rd} epitaxial layer 533″ of the MSE layers in the OCB region T_{OCB}, and the buffer epitaxial layer 502″ has a doping concentration D_{B} lower than each of the MSE layers in the OCB region T_{OCB}.

Please refer to FIG. 5D for a cross-sectional view showing another preferred embodiment along A2-A2′ line of FIG. 3A with new and improved device structure having multiple stepped epitaxial layers wherein the doping concentration variations as grown are depicted along the vertical direction. The N-channel trenched semiconductor power device has a similar structure to FIG. 5C, except that in FIG. 5D, the buffer epitaxial layer 502′″ has a doping concentration D_{B} higher than a top layer of the MSE layers in the OCB region T_{OCB} but lower than other layers of the MSE layers in the OCB region T_{OCB}.

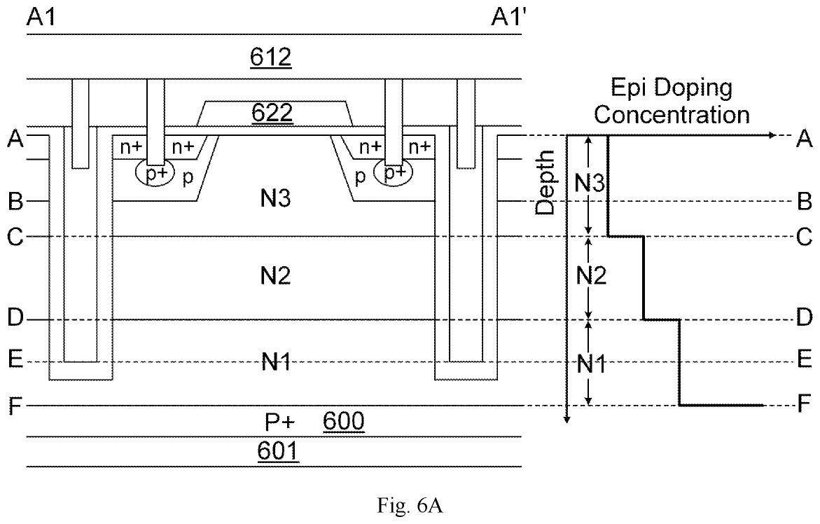

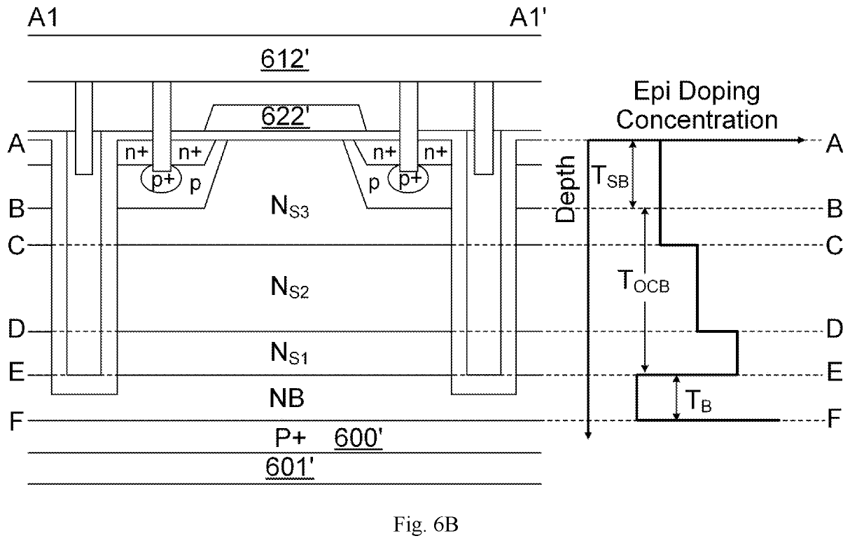

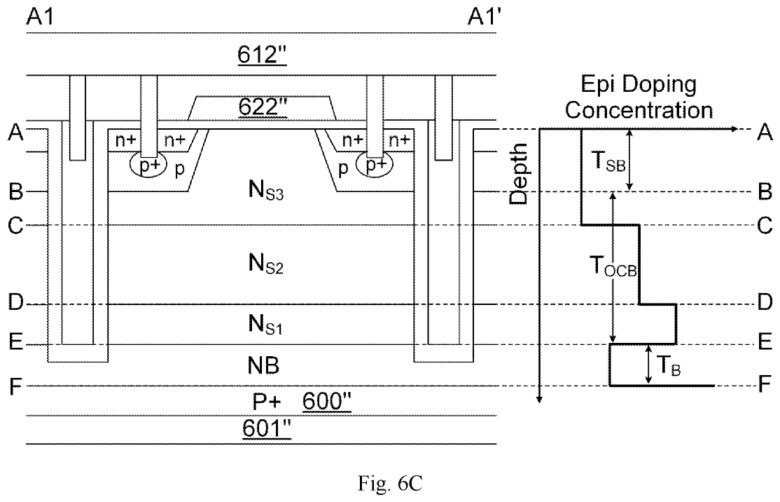

Please refer to FIG. 6A for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device representing an IGBT device has a similar structure to FIG. 4A, except for the different substrate. In this invention, the IGBT is formed onto a P+ substrate 600.

Please refer to FIG. 6B for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device representing an IGBT device has a similar structure to FIG. 4C, except for the different substrate. In this invention, the IGBT is formed onto a P+ substrate 600′.

Please refer to FIG. 6C for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device representing an IGBT device has a similar structure to FIG. 4D, except for the different substrate. In this invention, the IGBT is formed onto a P+ substrate 600″.

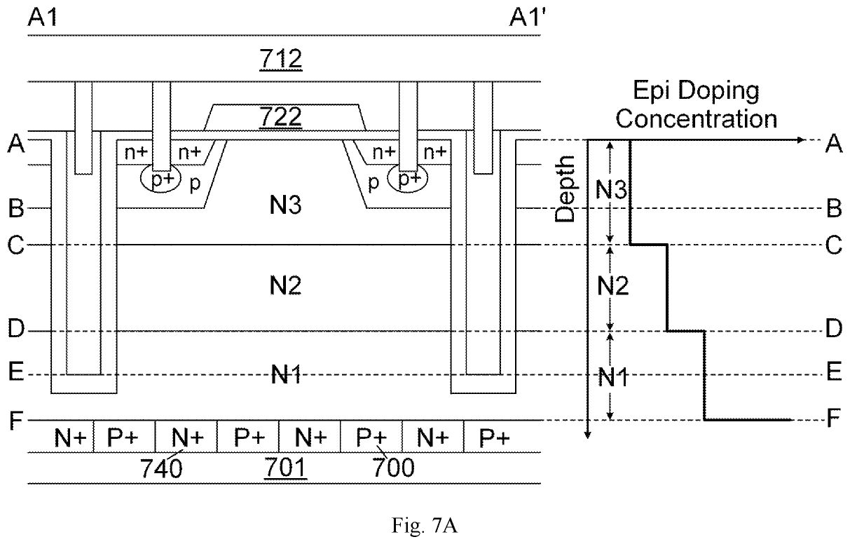

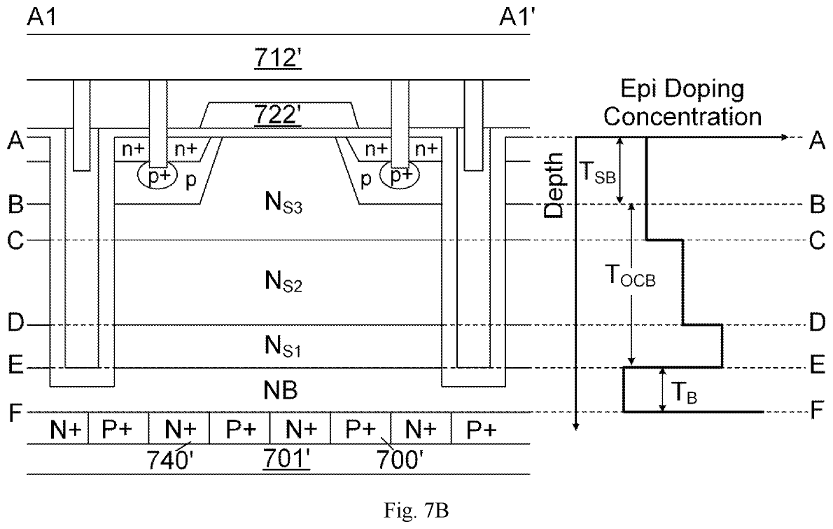

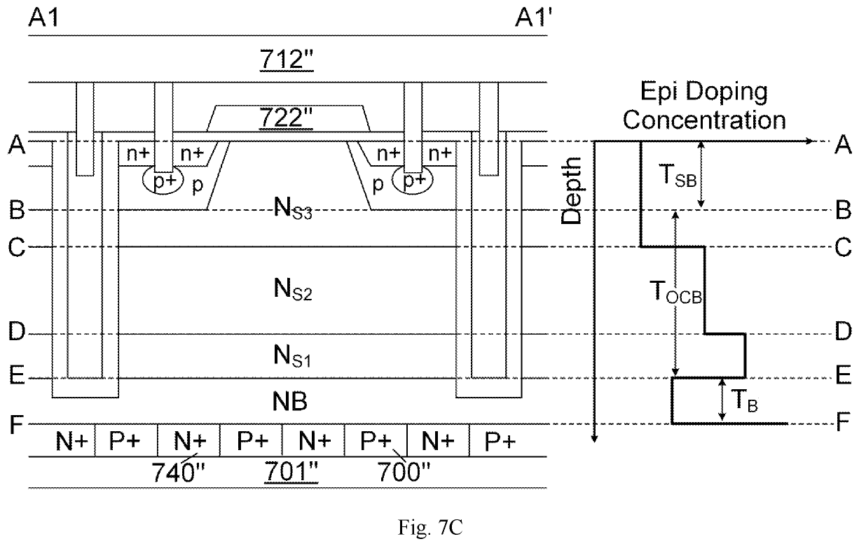

Please refer to FIG. 7A for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device has a similar structure to FIG. 6A, except that, the IGBT in FIG. 7A further comprises a plurality of heavily doped N+ regions 740 formed in the P+ substrate 700 to form a plurality of alternating P+ and N+ regions in the substrate.

Please refer to FIG. 7B for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device has a similar structure to FIG. 6B, except that, the IGBT in FIG. 7B further comprises a plurality of heavily doped N+ regions 740′ formed in the P+ substrate 700′ to form a plurality of alternating P+ and N+ regions in the substrate.

Please refer to FIG. 7C for a cross-sectional view showing another preferred embodiment along A1-A1′ line of FIG. 2A with new and improved device structure having three stepped epitaxial layers wherein the doping concentration variations are depicted along the vertical direction according to the present invention. The N-channel trenched semiconductor power device has a similar structure to FIG. 6C, except that, the IGBT in FIG. 7C further comprises a plurality of heavily doped N+ regions 740″ formed in the P+ substrate 700″ to form a plurality of alternating P+ and N+ regions in the substrate.

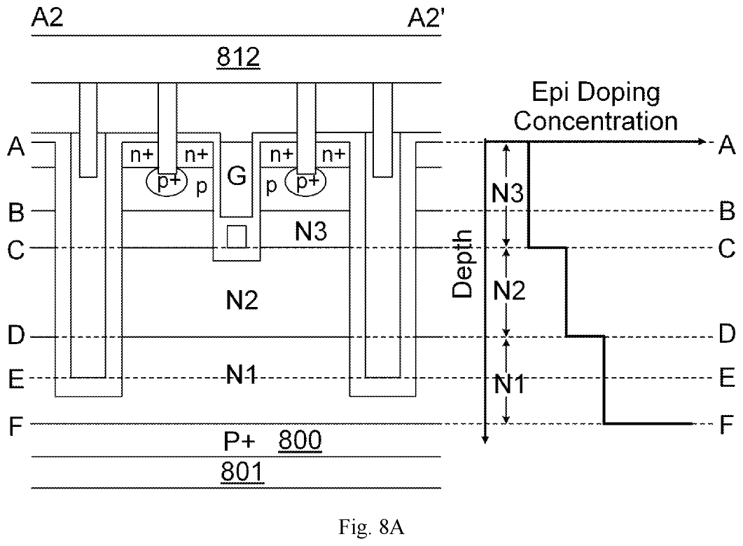

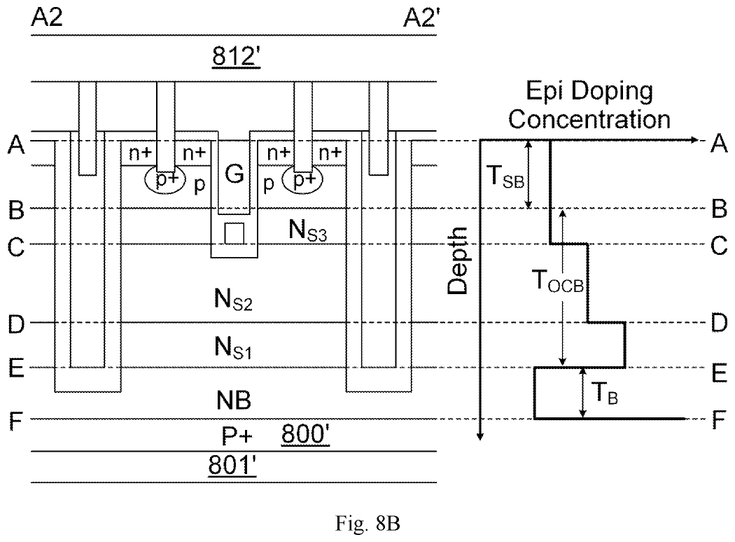

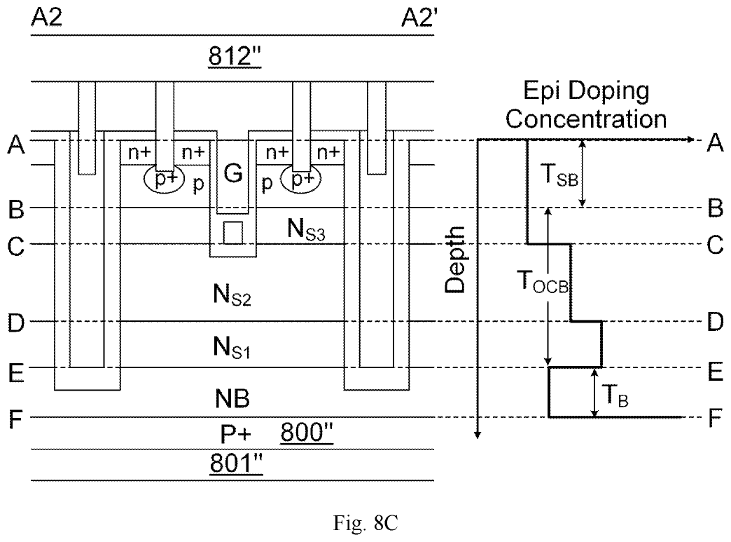

Please refer to FIG. 8A for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device representing an IGBT device has a similar structure to FIG. 5A, except for the different substrate. In this invention, the IGBT is formed onto a P+ substrate 800.

Please refer to FIG. 8B for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device representing an IGBT device has a similar structure to FIG. 5C, except for the different substrate. In this invention, the IGBT is formed onto a P+ substrate 800′.

Please refer to FIG. 8C for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device representing an IGBT device has a similar structure to FIG. 5D, except for the different substrate. In this invention, the IGBT is formed onto a P+ substrate 800″.

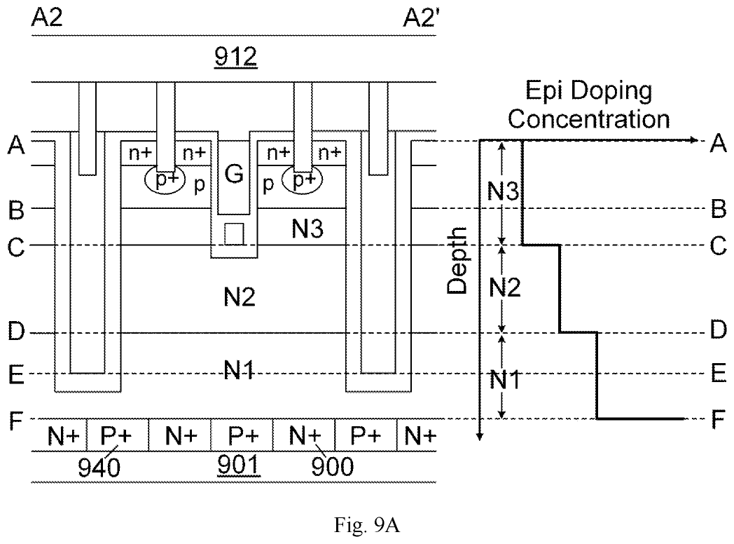

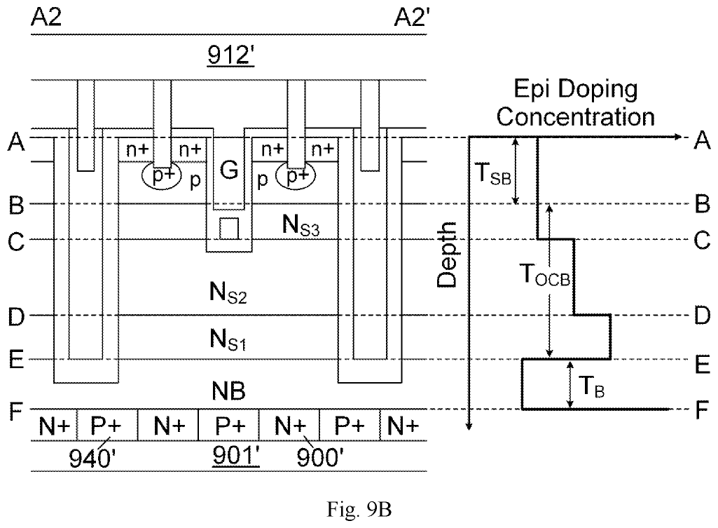

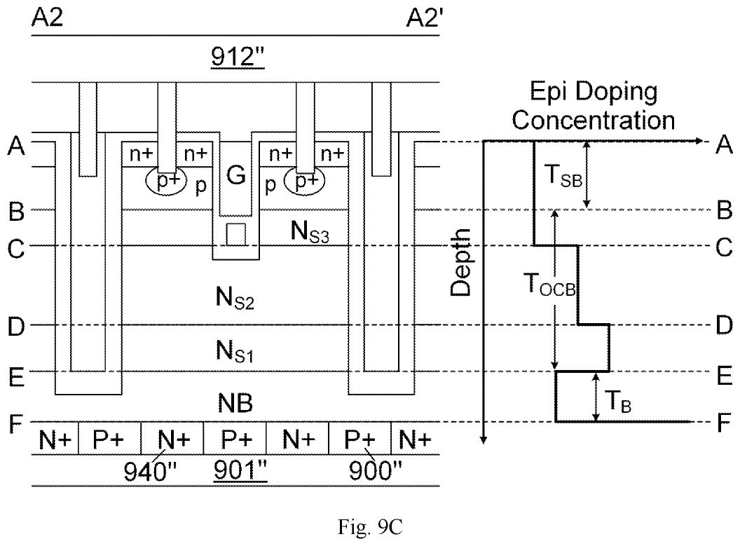

Please refer to FIG. 9A for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device has a similar structure to FIG. 8A, except that, the IGBT in FIG. 9A further comprises a plurality of heavily doped N+ regions 940 formed in the P+ substrate 900 to form a plurality of alternating P+ and N+ regions in the substrate.

Please refer to FIG. 9B for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device has a similar structure to FIG. 8B, except that, the IGBT in FIG. 9B further comprises a plurality of heavily doped N+ regions 940′ formed in the P+ substrate 900′ to form a plurality of alternating P+ and N+ regions in the substrate.

Please refer to FIG. 9C for a cross-sectional view showing another preferred embodiment along A2-A2′ line of FIG. 3A with new and improved device structure having three stepped epitaxial layers wherein the doping concentration variations are depicted along the vertical direction according to the present invention. The N-channel trenched semiconductor power device has a similar structure to FIG. 8C, except that, the IGBT in FIG. 9C further comprises a plurality of heavily doped N+ regions 940″ formed in the P+ substrate 900″ to form a plurality of alternating P+ and N+ regions in the substrate.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A shielded gate trench (SGT) device comprising a plurality of unit cells with each unit cell in an active area, comprising:
a planar gate poly silicon layer as a planar gate electrode having a hexagonal shape surrounding a deep trench with a hexagonal shape wherein a shielded gate electrode is formed within said deep trench and surrounded by an insulating film;
a source-body contact with a hexagonal shape disposed between said planar gate electrode and said deep trench;
an epitaxial layer of said first conductivity type grown on a substrate;
a source region of said first conductivity type formed near a top surface of said epitaxial layer within said active area;
a body region of said second conductivity type formed underneath said source region;
said planar gate electrode made of a doped poly-silicon layer padded by a gate oxide layer, and
said shielded gate electrode, said source and body regions shorted together through a source metal.

2. The SGT device of claim 1, wherein said epitaxial layer is a single epitaxial layer with a uniform doping concentration.

3. The SGT device of claim 1, wherein said epitaxial layer has multiple stepped epitaxial (MSE) layers with doping concentrations decreasing stepwise in a direction from said substrate toward said body region along sidewalls of said deep trench.

4. The SGT device of claim 1, wherein said epitaxial layer has multiple stepped epitaxial (MSE) layers with doping concentrations decreasing stepwise in a direction from a bottom of said shielded gate electrode toward said body region along sidewalls of said deep trench, and a buffer epitaxial layer between a bottom of said shielded gate electrode and said substrate, said epitaxial layer in said buffer region has a doping concentration lower than each of said MSE layers.

5. The SGT device of claim 1, wherein said epitaxial layer has multiple stepped epitaxial (MSE) layers with doping concentrations decreasing stepwise in a direction from a bottom of said shielded gate electrode toward said body region along sidewalls of said deep trench, and a buffer epitaxial layer between a bottom of said shielded gate electrode and said substrate, said epitaxial layer in said buffer region has a doping concentration higher than a top layer of said MSE layers but lower than other layers of said MSE layers.

6. The SGT device of claim 1, wherein said substrate has said first conductivity type.

7. The SGT device of claim 1, wherein said substrate has said second conductivity type.

8. The SGT device of claim 7, further comprising a plurality of heavily doped regions of said first conductivity type in said substrate to form a plurality of alternating P+ and N+ regions in said substrate.

9. The SGT device of claim 1, wherein said source-body contact is a trenched contact filled with a metal plug.

10. The SGT device of claim 1, wherein a bottom of said deep trench is located above or below a top surface of said substrate.

11. A shielded gate trench (SGT) device comprising a plurality of unit cells with each unit cell in an active area, comprising:
a gate trench having a hexagonal shape and surrounding a deep trench with a hexagonal shape wherein a first type shielded gate electrode is formed within said deep trench and surrounded by a first insulating film;
a source-body contact with a hexagonal shape disposed between said gate trench and said deep trench;
an epitaxial layer of said first conductivity type grown on a substrate;
said deep trench having deeper trench depth than said gate trench; and
said gate trench surrounded by a source region of said first conductivity type is encompassed in a body region of a second conductivity type near a top surface of said epitaxial layer.

12. The SGT device of claim 11, wherein said gate trench is filled with a gate electrode and a second type shielded gate electrode; said second type shielded gate electrode is insulated from said epitaxial layer by a second insulating film, said gate electrode is insulated from said epitaxial layer by a gate oxide, said second type shielded gate electrode and said gate electrode are insulated from each other by an (Inter-Poly Oxide) IPO film, said gate oxide surrounds said gate electrode and has less thickness than said second insulating film.

13. The SGT device of claim 11, wherein said epitaxial layer is a single epitaxial layer with a uniform doping concentration.

14. The SGT device of claim 11, wherein said epitaxial layer has multiple stepped epitaxial (MSE) layers with doping concentrations decreasing stepwise in a direction from said substrate toward said body region along sidewalls of said deep trench.

15. The SGT device of claim 11, wherein said epitaxial layer has multiple stepped epitaxial (MSE) layers with doping concentrations decreasing stepwise in a direction from a bottom of said first type shielded gate electrode toward said body region along sidewalls of said deep trench, and a buffer epitaxial layer between said bottom of said first type shielded gate electrode and said substrate, said epitaxial layer in said buffer region has a doping concentration lower than each of said MSE layers.

16. The SGT device of claim 11, wherein said epitaxial layer has multiple stepped epitaxial (MSE) layers with doping concentrations decreasing stepwise in a direction from a bottom of said first type shielded gate electrode toward said body region along sidewalls of said deep trench, and a buffer epitaxial layer between said bottom of said first type shielded gate electrode and said substrate, said epitaxial layer in said buffer region has a doping concentration higher than a top layer of said MSE layers but lower than other layers of said MSE layers.

17. The SGT device of claim 11, wherein said substrate has said first conductivity type.

18. The SGT device of claim 11, wherein said substrate has said second conductivity type.

19. The SGT device of claim 18, further comprising a plurality of heavily doped regions of said first conductivity type in said substrate to form a plurality of alternating P+ and N+ regions in said substrate.

20. The SGT device of claim 11, wherein a bottom of said deep trench is located above or below a top surface of said substrate.
